(19) United States
(12) Patent Application Publication
(10) Pub. No.: US 2011/0117757 A1
(43) Pub. Date: May 19, 2011

(54) CONTACTING OF MULTIPOINT PLUG CONNECTORS VIA INTERMEDIATE PRINTED-CIRCUIT BOARDS

(76) Inventors: Jochen Seibold, Tuebingen (DE); Bernd Eckert, Vaihingen An Der Enz (DE)

(21) Appl. No.: 12/990,870

(22) PCT Filed: Apr. 2, 2009
(86) PCT No.: PCT/EP09/53913

§ 371 Date: Feb. 3, 2011

(30) Foreign Application Priority Data
May 5, 2008 (DE) 102008001557.1

(51) Int. Cl. H01R 12/00; H05K 3/36

(52) U.S. Cl. 439/83; 29/825; 439/78

(57) ABSTRACT

A plug strip connection, including a plug connector strip, a main board having terminals and an intermediate circuit board. The plug connector strip includes a group of individual connecting elements which extend at an angle to the intermediate circuit board and are fastened to the latter. The intermediate circuit board extends at an angle to the main board and is fastened to it. The individual plug connecting elements are electrically connected to the terminals via the intermediate circuit board. A method for producing a plug strip connection is also described. A plug-and-socket connector strip, a main board having terminals and an intermediate circuit board are provided. A group of individual plug connecting elements is positioned as a plug connector strip, and the plug connector strip is fastened to the intermediate circuit board, individual plug connecting elements extending perpendicular to the intermediate circuit board; electrical contacts being set up between the intermediate circuit board and the plug connector strip and the intermediate circuit board being fastened to the main board, the intermediate circuit board extending perpendicularly to the main board. In addition, the method includes: setting up electrical contacts between the main board and the intermediate circuit board.

### FIELD OF THE INVENTION

The present invention relates to a plug connector system, including a multipoint plug connecting system such as is used for engine control units in motor vehicles.

### BACKGROUND INFORMATION

Plug connectors are used for the electrical connection of electrical components, which are provided as individual modules, the plug connectors being used for the connection of connecting cables. In the case of a multitude of contacts, these are arranged as a strip having one or more rows. Consequently, an electrical connection may be provided using pins which are plugged into a printed-circuit board and are connected to it electrically.

German Patent No. DE 42 44 626 A1 describes a plug connection between two printed-circuit boards which are situated perpendicular to each other. One of the printed-circuit boards includes a contacting device into which the other printed-circuit board is plugged perpendicularly, using guide elements. Thus, an angled plug strip connection is shown.

U.S. Published Application No. 2005/0085103 A1 describes two printed circuit boards that are at an angle to each other perpendicularly, an intermediate element being used as a prismatic wedge, and the two elements being connected to each other mechanically. Inside the prismatic wedge, flexible, bent lines are shown which provide the electrical connection between the two printed circuit boards. The contacting shown is thus based on flexible, bent lines.

German Patent Application No. DE 10 2006 005 045 A1 describes a plug connection device which carries a double-walled component, the double-walled component has a hollow space in which contacts are provided that are able to be reached via bores. The bores are provided for plugging in a plug element that bears a group of pins. The device shown is thus equipped with a single printed circuit board that bears a hollow body in which all the electrical contact elements of the component are provided.

In many fields of application, it is advantageous to be able to use a horizontal connector outlet, by which the costly producing and bending off contact pins may be omitted. In the case of straight pins, for the continuation of the electrical connection in another plane, a flexible connection is required, for instance, a partially flexible “Semi-Flex” printed circuit board. The continuation of the electrical connection in another plane is often determined by the application, and is necessary because of mounting support, other modules or because of lack of space.

Such a flexible intermediate connection is costly, however, and requires complex processing steps which further increase the effort.

### SUMMARY

An object of the present invention is to provide such a plug connection system that may be produced more cost-effectively and with less effort.

The present invention permits a more cost-effective and simpler electrical connection for plug strip systems. In particular, production is simplified, since all the elements are able to be made of the same basic elements, i.e., printed-circuit boards, the connecting technology being able to be implemented by conventional soldering methods. In addition, the present application enables a simple connection by inserting into slots, for instance, into one or more slots of a main board. The present invention may be provided using cost-effective materials, in particular, the plug connection according to the present invention may be implemented without costly flexible printed-circuit boards or similar conductors. The intermediate circuit board according to the present invention, which replaces the flexible connection, besides the electrical connection, may also provide circuits, for instance, by equipping the intermediate circuit board with electrical components. In contrast to plug systems having flexible connections, which cannot carry any components directly, it thus becomes possible, for example, that electrical components, that form an EMV filter, are situated closer to a plug connector strip. Because of that, one is able to achieve a better filter effect especially in the case of high-frequency signals. Whereas conventionally, the flexible connection elements have only contributed to a deterioration in the electromagnetic compatibility, when using the plug strip connection according to the present invention, it is possible that the intermediate circuit board used there, by contrast to this, has filter properties or filter components which clearly increase the electromagnetic compatibility.

The intermediate circuit board used in the plug strip connection according to the present invention, by contrast to the conventional flexible connecting elements, is able to fulfill an additional function, that is, the carrying of the pins or of individual plug connecting elements which form a plug connector strip. Furthermore, the present invention enables a simple and cost-effective mounting of individual plug connecting elements on the intermediate circuit board, in order to connect the individual plug connecting elements mechanically to one another. The individual plug connections may be mounted on the intermediate circuit board by pressing it in, or may be soldered to it. Because of that, one may use conventional cost-effective connecting mechanisms, in contrast to flexible connectors such as a flexible printed circuit board, in the case of which the individual plug connections are able to be connected only using certain effortful connecting techniques.

In accordance with the present invention, an intermediate circuit board is used for relocating connecting planes, that is, for connecting a plug connecting strip to a main board which preferably runs parallel to the plug connecting strip. For the connection, the intermediate circuit board is positioned at an angle to the main board and at an angle to the plug connecting elements of the plug connecting strip, and is soldered to these, for example, connected via a plug connection, or a combination thereof. The extension direction of the individual plug connecting elements, especially the extension direction of the plug connecting pins, is thus relocated removed from the main board, the relocation being provided by the intermediate circuit board. In order to achieve that the plug connecting elements extend parallel to the main board relocated for this, the intermediate circuit board is placed at an angle both to the plug connecting elements and to the main board preferably at the same angle, such as 90°. The main board is thus relocated to the plug connecting elements extending longitudinally in a direction which lies in a normal plane of the extension direction of the plug connecting elements. The relocation direction is preferably perpendicular to the direction of extension of the plug connecting elements and perpendicular to the direction in which the plug connecting strip extends.

The longitudinal extension direction of the plug connecting strip, the transverse extension of the main board and the transverse extension of the intermediate circuit board are preferably parallel to one another. Thus, in cross section, the plug strip connection preferably forms a stair shape, the plug connecting elements being perpendicular to the intermediate circuit board subsequent to them, and the intermediate circuit board, in turn, is perpendicular to the main board that is subsequent to it. The plug connecting elements have at least sections that extend to a first direction, the main plate extending at least partially from the intermediate circuit board in a second direction, which is perpendicular to the first direction.

In order to provide a connection between the plug connecting elements and the main board, the intermediate circuit board preferably includes at least one and preferably two outer layers, which are provided as conductor layers. The two outer layers may be patterned without difficulty by conventional measures (for instance, photolithography), so that any individual combinations between plug connecting elements and the main board may be provided. The main plate also includes at least one, and preferably two outer layers, which are also provided as a conductor layer, and which implements a contact connection for the intermediate circuit board impinging upon it. The outer layer(s) is/are also able to include solder pads or other contact elements for the completion of electric components, such as filter components, and the like.

The plug connecting elements are preferably individual plug connecting elements and have a lengthwise extended shape. Depending on the application, the plug connecting elements are developed as pins or sockets, and pressed into the intermediate circuit board, partially plugged in, soldered to it, or a combination thereof. For this purpose, the intermediate circuit board preferably includes recesses, such as through-holes into which the individual plug connecting elements are plugged, each plug connecting element preferably having a contact, that is only allocated to this plug connecting element, which is provided on the intermediate circuit board and is connected only to the associated plug connecting element. At the same time, this contact is continued by the intermediate circuit board, and reaches the main board via an additional electrical connection between the main board and the intermediate circuit board. Consequently, the individual plug connections are clearly assigned to a contact or a printed circuit trace or a contact pad of the printed circuit board.

Besides the electrical connection, the plug connecting strip provides a mechanical stabilization or positioning of the plug connecting elements, so that these may be provided in grouped form. The grouping of the individual plug connecting elements preferably corresponds to a row or a plurality of parallel rows that have the same length, the individual plug connecting elements being in a predetermined grid and being preferably at a uniform distance from one another, and being plugged into the intermediate circuit board in one line or in lines that are parallel to one another. The grouping may also take place in several subgroups, for instance, a first subgroup providing a periodic linear arrangement being at a little distance apart and having thin plug connecting elements, and an additional subgroup being provided having thick, or rather, thicker plug connecting elements which are arranged at a greater distance from one another. The thinner plug connecting elements or the corresponding subgroup are/is able to be allocated to a parallel interface for signals, such as controls signals, the thicker connecting elements, having a greater distance or the corresponding subgroup corresponds to a power terminal, for instance, an output stage. The intermediate circuit board may carry different subgroups having the same or different functions.

The intermediate circuit board is preferably equipped with connecting elements which are provided using a conductor layer or using a plurality of conductor layers. Connecting elements are used, for one thing, for the direct electrical contact to the main board, and for another thing, for the direct electrical contact to the plug connecting elements, as well as for the electrical connection of the plug connecting elements to conductors on the main plate. In addition, the intermediate circuit board may have further connecting elements, such as contact pads, soldering connections and/or electrically connecting plug connections which are preferably provided between the plug connecting strip and the main plate, these connecting elements being provided for the connection of electrical electronic components, which are located on at least one of the surfaces of the intermediate circuit board. Consequently, electrical or electronic components may be mounted on the intermediate circuit board and connected to it, by SMD technique, for instance, by stick through technique or by other techniques, the components preferably being SMD components that are connected to the intermediate circuit board via contact pads. The components may be active or passive components, and the most suitable are filter components, and therefore capacitors or inductors, preferably SMD capacitors occupying little space and having a high relative dielectric constant. Furthermore, the components may be smaller assemblies which provide an electronic filter.

For the mechanical connection of the intermediate circuit board to the main board, these may be soldered together, which represents an electrical connection at the same time. The main board preferably includes slots into which the intermediate circuit board, or one end of the intermediate circuit board, is inserted, whereby a further mechanical stabilization comes about. The ports or the ends of the intermediate circuit board may be designed and may have complementary electric contacts in such a way that an electrical contact also comes about by inserting into the slots. To simplify the assembly and for the stable fastening of the intermediate circuit board to the main board, the intermediate circuit board (or the main board) may be equipped with grid elements for stabilizing the plug connection, that is provided by the slots in the main board and by one end of the intermediate circuit board. The main board may include a slot or several slots, the intermediate circuit board preferably including at one end complementary counterpieces which, in response to inserting using the slots (or rather, inserting into the slots) produce a press fit for the main board. The electrical connecting elements between the intermediate circuit board and the main board are preferably provided on the side of the intermediate circuit board, at an edge, or an end of the intermediate circuit board. Contacts are preferably provided at this end of the intermediate circuit board, so as to provide the electrical connection to the main board.

When the intermediate circuit board carries components, electronic components, for instance, which work as EMV filters, contacts of the plug connecting strip may be connected via these components to printed circuit traces that are located at one edge of the intermediate circuit board, the edge extending from the plug connector strip to the main board. This edge may also extend along the plug connector strip and along the main board, that is, at the contact location between the main board and the intermediate circuit board. At the connecting location between the intermediate circuit board and the main board, pads or printed circuit trace terminals are preferably provided, which are connected to one another via soldering connections. The mounting and the electrical contacting of the intermediate circuit board meeting the main board, and of the main board itself is preferably provided by conventional connecting techniques between “daughter boards” and “mother boards”. Conventional connecting techniques may be used, by which one may connect printed circuit boards to each other, that are at an angle to each other.

The intermediate circuit board may be made of one part or several parts, that is, subdivided into segments, each segment extending between the main board and the plug connector strip, and the segments being separate from one another in the longitudinal direction of the plug connector strip. This permits the reduction of mechanical stresses which, for example, are caused by different thermal coefficients of expansion.

The plug connecting elements, in a grouped manner, preferably form a multipoint plug connector, a female multipoint connector, a male pin connector or a pin header. Depending on the design of the plug connecting elements (male/female), the strip may be designed as a plug multipoint connector, a female multipoint connector or a tab multipoint connector. The plug connecting elements are designed as pegs or pins, and, in the case of female multipoint connectors, they have a section that includes an accommodating element in the form of a socket, to which is adjacent a pin section for mounting in through-holes, such as bores in a printed circuit board. The plug connecting elements may have the shape of wire sections, preferably having a constant cross section, the diameter of the wire being adapted to the purpose, and especially to the current-carrying capacity.

For the purpose of fastening, besides snap-in elements, guide elements or end stops may also be provided, which are situated individually or as a combination on the printed circuit board, on the intermediate circuit board or on both printed-circuit boards, or are mechanically fastened to them.

In one preferred specific embodiment, the individual plug connections which, as a group, form the plug-and-socket connector, connected to one another via a plug or socket element, which connects the plug connecting elements mechanically to one another, but insulates them from one another electrically. The plug element (or the socket element) preferably includes extruded insulating material that surrounds the individual plug connecting elements or into which the plug connecting elements are sunk. The plug connecting elements may equally be sunk into or pressed into the intermediate circuit board. As a further example, the plug element (or the socket element) may be plugged onto the plug-and-socket connector, and thus onto the plug connecting elements. The plug element (or the socket element) may be collar-shaped and/or be provided by a plastic housing that is mechanically connected to the plug-and-socket connector. The plug strip connection may further include a plastic housing which forms a plug collar or a plug element, the plug collar or the plug element including insulating material which mechanically connects the plug connecting elements of the plug-and-socket connector to one another. The mechanical connection is preferably provided in that a prefabricated insulating material, which forms a plug collar and/or a plug element, is developed in one part with a plastic housing, and this is pushed onto the plug connecting elements of the plug-and-socket connector.

The individual plug connecting elements of the plug-and-socket connector are preferably pressed into the intermediate circuit board, which includes appropriate recesses, the plug connecting elements being able to be soldered either onto or into the intermediate circuit board or individually pressed into the intermediate circuit board, preferably using a single-pin insertion method.

In accordance with the present invention, a method may be provided which includes positioning the individual plug connecting elements as a plug-and-socket connector, for example, via a tool that is removable again or by introducing them into a plug element. The method also includes fastening of the plug-and-socket connector to the intermediate circuit board, the individual plug connecting elements, which form the plug-and-socket connector are mounted on, or introduced in the intermediate circuit board at an angle or preferably perpendicularly. By introducing the plug connecting elements, a pressure fit is preferably brought about with the intermediate circuit board. Furthermore, the method includes setting up an electrical contact between the intermediate circuit board and the plug-and-socket connector, this including: The introduction of the plug connecting elements into the intermediate circuit board, soldering of the plug connecting elements to contacts of the intermediate circuit board (pads, for example) or a combination of these. The present invention also provides fastening the intermediate circuit board to the main board, preferably by plugging it in, by soldering an edge or an end of the intermediate circuit board to appropriate contacts or contact fields of the main board, or perhaps by plugging the intermediate circuit board into a plug element that is connected to the main board. By fastening the intermediate circuit board to the main board, an electrical contact is preferably produced, the electrical contact being also able to be provided by soldering connections between the main board and the intermediate circuit board.

The setting up of electrical contacts, especially between the main board and the intermediate circuit board, is provided by plugging in or soldering contact surfaces which are provided on the intermediate circuit board and the main board. The contact surfaces are preferably formed by conductor layers of the main board or the intermediate circuit board. For this purpose, the intermediate circuit board and/or the main board include at least one conductor layer which is patterned so as to develop printed circuit traces and contact surfaces. These are preferably electrically connected to one another by soldering. The fastening of the intermediate circuit board to the main board may be provided by plugging the printed circuit board into a slot in the main board. By doing this, a mechanical, electrical or electromechanical connection comes about between the intermediate circuit board and the main board.

Furthermore, the method preferably provides mechanically connecting to one another individual plug connecting elements of the plug-and-socket connector by extruding using an insulating material, or providing the mechanical connection in that the plug connecting elements are sunk into an element, preferably made of an insulating material, or by plugging or pushing insulating material onto the plug-and-socket connector. The insulating material may form a prefabricated element which preferably forms a plug collar and/or a plug body, for instance, a tub plug connector. The insulation material may be formed as one part or a plurality of parts.

The main board, the intermediate circuit board or both printed circuit boards are preferably stiff printed circuit boards, such as epoxy printed circuit boards or synthetic-resin-bonded paper sheet printed circuit boards. The printed circuit boards are preferably planar, and may be developed on one side or on both sides to be copper-coated.

### BRIEF DESCRIPTION OF THE DRAWINGS

Exemplary embodiments of the present invention are shown in the figures and explained in greater detail below.

FIG. 1 shows a cross section through an example plug strip connection according to the present invention.

FIG. 2 shows a perspective illustration of an example plug strip connection according to the present invention.

### DETAILED DESCRIPTION OF EXAMPLE EMBODIMENTS

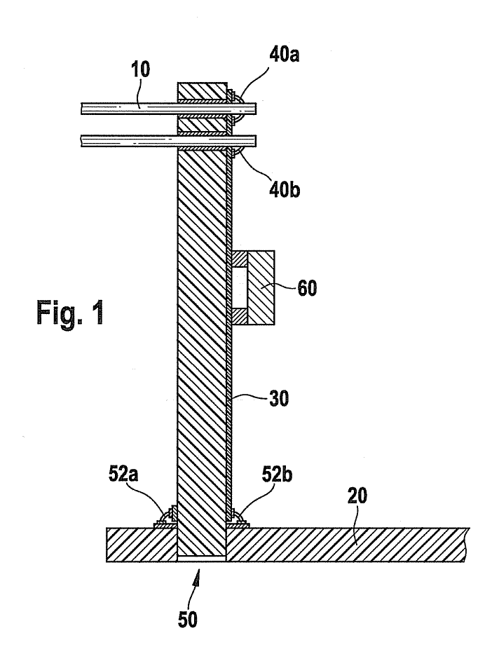

FIG. 1 shows an example plug strip connection shown in cross section, which includes a plug connector strip 10, a main board 20, as well as an intermediate circuit board 30. Plug connector strip 10 is constructed in two rows, and in the cross sectional illustration of FIG. 1, only one individual plug connecting element of the upper row and one individual plug connecting element of the lower row being shown. The individual plug connecting elements, which form plug connector strip 10, are inserted into an intermediate circuit board 30, which thus connects plug connector strip 10 to main board 20. On one side of the upper section of intermediate circuit board 30, electrical connections 40a, b are provided, which, by contact surfaces on intermediate circuit board 30 and by a soldering connection, connect the individual plug connecting elements of plug connector strip 10 to intermediate circuit board 30. Moreover, plug connector strip 10 includes connections which connect the upper section to a lower section of intermediate circuit board 30. In the lower section, plug connector strip 10 is inserted into main board 20, main board 20 having a slot 50 which, together with one end of intermediate circuit board 30, forms a press fit. For the electrical connection and for the additional mechanical connection, contacts 52a, b are also provided at the lower section of intermediate circuit board 30, which, via conductor layers of intermediate circuit board 30 and of main board 20, as well as via soldering connections (shown in outline) connect intermediate circuit board 30 electrically and mechanically to main board 20. Intermediate circuit board 30 also carries, for instance, a component 60, which is used, for example, for EMV filtering, which is in contact with connections (not shown) which connect contact locations 40a, b to contact locations 52a, b. Consequently, intermediate circuit board 30 preferably carries connecting elements which connect each individual plug connecting element to a terminal (not shown) of main board 20. Thus, each individual plug connecting element is able to be contacted electrically via main board 20.

In FIG. 1, the plug connecting elements extend horizontally from intermediate circuit board 30 starting towards the left, and are perpendicular to a plane in which intermediate circuit board 30 runs. The plane in which intermediate circuit board 30 runs is, in turn, perpendicular to main board 20. There is preferably an angulation of 90° in each case between main board 20, intermediate circuit board 30 and the extension direction of the plug connecting elements, other angles too, however, being able to be taken up, which are preferably equal between main board 20 and intermediate circuit board 30, as well as between intermediate circuit board 30 and the plug connecting elements.

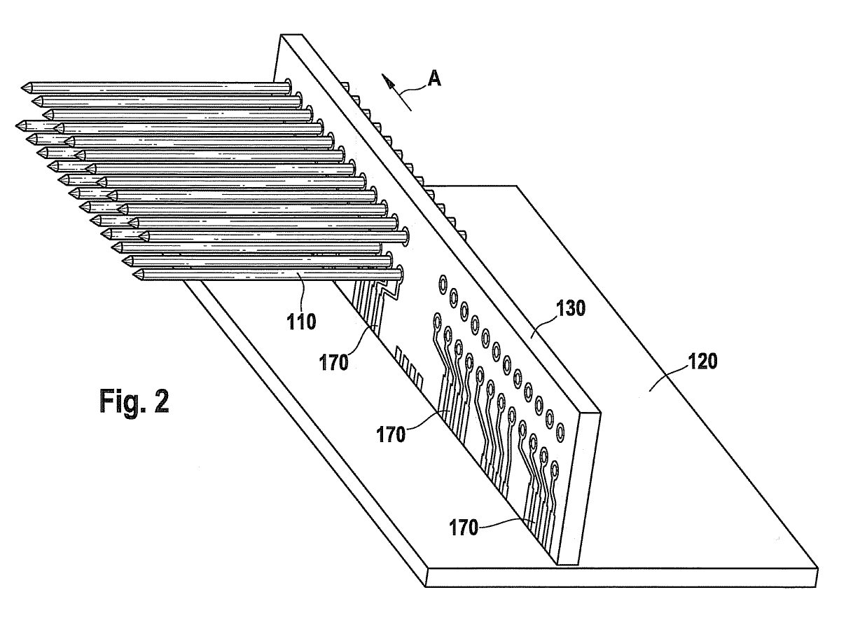

FIG. 2 shows a perspective representation of a plug strip connection according to the present invention, having a main board 120 and an intermediate circuit board 130 at a perpendicular angle to it, in which individual plug connecting elements are inserted. Consequently, the plug connecting elements extend in a direction that is parallel to main board 120. The individual plug connecting elements are grouped in a longitudinal direction in which the entire plug connector strip 110 extends, extension direction A of plug connector strip 110 running parallel to intermediate circuit board 130 and parallel to main board 120. The extension direction of plug connector strip 110 (i.e., the grouping of the individual plug connecting elements) is thus perpendicular to the extension direction of the individual plug connecting elements.

FIG. 2 also shows printed-circuit traces 170, which connect contact surfaces of intermediate circuit board 130, that connect intermediate circuit board 130 to plug connector strip 110, at a lower section of intermediate circuit board 130 connect to corresponding contacts (not shown) of main board 120. Intermediate circuit board 130 includes through-holes, which are developed at least on one side of intermediate circuit board 130 to have a circular contact surface, the through-holes also preferably having a cylindrical metal layer within intermediate circuit board 130, which extends perpendicularly all the way through intermediate circuit board 130. The contact surfaces provided inside intermediate circuit board 130, and about the individual plug connecting elements, are used for the electrical contacting of plug connecting elements, as well as for fastening the plug connecting elements to intermediate circuit board 130. The contact surfaces, in turn, are connected electrically to main board 120 via printed-circuit trace 170, so that terminals of main board 120 make possible an electrical through-contacting to the individual plug connecting elements.

The dimensions of the plug strip connection shown are not to scale, in particular, the individual thicknesses of main boards 120 are able to be in a different ratio to the longitudinal and lateral dimensions of the other components of the plug strip connection from that shown.

By contrast to FIG. 1, in which intermediate circuit board 130 is inserted into a slot in the main board, intermediate circuit board 130 is connected at one end to the surface of main board 120, without intermediate circuit board 130 extending into main board 120.

1-10. (canceled)

11. A plug strip connection, comprising:
a plug connector strip;
a main board having terminals; and
an intermediate circuit board;
wherein the plug connector strip includes a group of individual plug connecting elements which extend at an angle to the intermediate circuit board and are fastened on the intermediate circuit board, the intermediate circuit board extends at an angle to the main board and is fastened on the main board, and the individual plug connecting elements are electrically connected to the terminals via the intermediate circuit board.

12. The plug strip connection as recited in claim 11, wherein the plug connector strip, the main board and the intermediate circuit board extend longitudinally in a same direction, the direction being parallel to the main board and parallel to the intermediate circuit board.

13. The plug strip connection as recited in claim 11, wherein the individual plug connecting elements extend all the way through the intermediate circuit board and are connected to at least one conductor layer of the intermediate circuit board via the individual plug connecting elements in an electrically conductive manner.

14. The plug strip connection as recited in claim 13, wherein the individual plug connecting elements are connected to the at least one conductor layer of the intermediate circuit board via one of soldering connections or press fit connections.

15. The plug strip connection as recited in claim 11, wherein the intermediate circuit board has at least one conductor layer, which is patterned in printed circuit traces, and which have electrical connecting elements for connecting one of the main board, contact pads, soldering connections or electrically connecting plug connections for connecting the main board.

16. The plug strip connection as recited in claim 11, wherein the intermediate circuit board has at least one conductor layer, which is patterned in printed circuit traces, and which has one of electrical connecting elements for the main board, contact pads, soldering connections, or electrically connecting plug connectors for connecting the main board.

17. The plug strip connection as recited in claim 11, wherein the intermediate circuit board has at least one conductor layer which is patterned in printed circuit traces, and which has electrically connecting plug connections for connecting components which are electrically connected to the intermediate circuit board using one of an SMD technique, stick-through technique, or by slipping on.

18. The plug strip connection as recited in claim 17, wherein the components include one of active or passive components.

19. The plug strip connection as recited in claim 11, wherein the intermediate circuit board is subdivided into at least two segments, which are physically separated from each other and which are mechanically connected to each other only one of via the main board, or via the individual plug, connecting elements.

20. The plug strip connection as recited in claim 11, wherein the main board has at least one slot into which the intermediate circuit board is inserted and via which the intermediate circuit board is fastened to the main board, the intermediate circuit board having soldering connections at the slot, which connect the intermediate circuit board to the main board, and at least one of the intermediate circuit board and the main board have at least one of end stops, guide elements, or snap-in elements, via which the intermediate circuit board is fastened mechanically to the main board.

21. The plug strip connection as recited in claim 11, wherein the plug connector strip includes one of a multipoint plug connector, a female multipoint connector, a tub plug connector strip or a pin header strip, which are designed as a plug strip, a tab multipoint connector or a female multipoint connector, which are provided by the individual plug connecting elements, the individual plug connecting elements being designed as one of pin elements, connecting elements or socket elements.

22. A method for producing a plug strip connection, comprising:
providing a plug connector strip, a main board having terminals and an intermediate circuit board;
positioning a group of individual plug connecting elements as the plug connector strip;
fastening the plug connector strip on the intermediate circuit board, individual plug connecting elements extending at an angle to the intermediate circuit board;
setting up electrical contacts between the intermediate circuit board and the plug connector strip;
fastening the intermediate circuit board to the main board, the inter mediate circuit board extending to the main board at an angle; and
setting up electrical contacts between the main board and the intermediate circuit board.

23. The method as recited in claim 22, further comprising:
one of setting up soldering connections by soldering the plug connector strip to the intermediate circuit board, or setting up press fit connections by pressing the plug connector strip into passages of the intermediate circuit board or using a single-pin insertion method, in which the individual plug connecting elements are pressed individually into the intermediate circuit board the electrical contacts being provided between a conductor layer of the intermediate circuit board and the individual plug connecting elements.

24. The method as recited in claim 22, further comprising:
setting up soldering connections by soldering at least one conductor layer, which is provided by the intermediate circuit board, to at least one conductor layer which is provided by the main board.

25. The method as recited in claim 22, further comprising:
inserting the intermediate circuit board into at least one slot, which is provided in the main board, the insertion of the intermediate circuit board producing one of a mechanical, an electrical or an electromechanical connection between the intermediate circuit board and the main board.

26. The method as recited in claim 22, further comprising:
mechanically connecting individual plug connecting elements of the plug connector strip by one of extruding using an insulation material, sinking the individual plug connecting elements of the plug connector strip into the insulating material, slipping or pushing insulating material onto the individual plug connecting elements of the plug connector strip, wherein the insulating material develops at least one of a plug collar or a plug body in one of a one-part form or a multi-part form.
